(19) United States
(12) Patent Application Publication
(10) Pub. No.: US 2015/0195954 A1
(43) Pub. Date: Jul. 9, 2015

(54) Distributed Computing And Combined Computation Exhaust Heat Recovery System

(71) Applicant: Lawrence Orsini, New York, NY (US)

(72) Inventor: Lawrence Orsini, New York, NY (US)

(21) Appl. No.: 14/149,650

(22) Filed: Jan. 7, 2014

(51) Int. Cl. H05K 7/20

(52) U.S. Cl. CPC H05K 7/20263; H05K 7/20763; H05K 7/20236; H05K 7/20272

(57) ABSTRACT

The present invention relates to a distributed computation and computation exhaust heat recovery system that converts beneficial computation load into usable heat or other forms of energy. Reclaimed heat from computer processors and memory can be used to heat hot water, conditioned spaces and used as a heat source for absorption refrigeration systems used for air conditioning and food refrigeration, etc. The system will use predictive algorithms to determine when occupants will require heat energy to ensure that the heat byproduct of that energy is available for each respective load listed above and that minimal heat is wasted or produced when it is not needed. The system will also employ various control strategies to optimize the efficiency of heat production and computation.

### BACKGROUND OF THE INVENTION

1. Field of the Invention

This invention relates generally to a heat recovery system and more particularly to a distributed computing and combined computation exhaust heat recovery system that controls heat production, recovery and conversion into usable heat and other forms of usable energy.

2. Description of Related Art

There exist large computation centers around the world. Within such a center large amounts of heat are produced by the workings of the computers. Such rooms need to be cooled in order for the components to keep working effectively and properly. Even within a smaller office or home environment where computers are in use there is a rather large output of heat that is not recycled or captured for reuse in a dedicated fashion. It is well known that when a computer performs computations it generates heat. A distributed computation model would generate a lot of heat that can be recovered and put into usable form. Regardless of the location or scale of computation, cooling the associated components disregards and disposes of the heat generated therein. If such heat could be saved and used for other purposes such as ancillary heating there would be a newfound source or energy that would become more cost effective than the current situation.

Heat recovery systems for recycling waste thermal energy from machines is known in the prior art. More specifically, by way of example, U.S. Pat. No. 6,938,417 B2 to Watanabe et al. discloses an exhaust heat recovery system that recovers exhaust that is generated by an electrical power generator for use in supplying hot water and air conditioning.

U.S. Pat. No. 6,050,226 to Shimada et al. discloses an exhaust heat recovery boiler in which an exhaust gas discharged from a gas turbine into a boiler duct to recover heat from the exhaust gas.

U.S. Pat. No. 6,942,027 to Klotten et al. discloses an exhaust-gas heat recovery appliance having a heat-exchanger line and a bypass line and a heat exchanger being arranged in the region of heat exchanger line.

There is no exhaust heat recovery system that are designed and configured for recovering heat generated by computation performed by computing systems. More particularly, there is no exhaust heat recovery system that can control the production of heat as well as recover and convert the heat energy given off from computer computation to allow for it to be recycled and used as an alternative form of heating and thus conserve energy accordingly.

Therefore, it is necessary to have a system that can control, recover and convert the heat energy given off from the computer computation device to become a recycled or newly usable heat form and source to be utilized for other applications. Moreover, the system should be able to take advantage of the distributed computation models which provides compensation of one form or another to optimize the efficiency of heat production and computation.

### SUMMARY OF THE INVENTION

One object of the present invention is to provide a method/system to transform the computation into a variable load that can be scaled up and down depending on heat needs. For example, if a household/building requires a large quantity of heat e.g. heating water, or hydronic heating, etc., the method/system can scale up the computation load so as to produce more heat to recover and transfer to usable heat/energy.

Another object of the present invention is to provide a method/system to recover the heat generated by computers from distributed computation system.

Another object of the present invention is to provide a method/system to convert the heat recovered into usable heat.

Yet another object of the present invention is to provide a method/system to control/optimize the heat production and distribution of said heat accordingly. At issue here is a regulatory process of allowing for second usage of heat produced in a methodical fashion. For example sending needed heat requirements on demand as it is called for and needed.

In an exemplary embodiment of the present invention a method/system is disclosed. Such method/system can transform the computation into a variable load that can be scaled up and down depending upon the requirement for heat. This transformation can be controlled/optimized by software included within the design of the system itself. Increasing the load on the processing units within a computer is a straightforward and controllable process. The system comprises at least one computing unit from which excess heat will be saved and reused for other purposes by, at least one heat recovering unit, software, and at least one sensor that will interact with a main computer unit. The computing unit generates heat while performing computation; the heat recovering unit converts the heat into usable heat or other forms of energy. The software is used to control timing and intensity of the computation used in the production of heat. The sensors including but not limited to temperature detectors are attached to the heat recovering unit so to control the computing unit's production of heat as well as collect and relay data back to the main computer. Such main computer contains processing capabilities for monitoring and regulating the flow of captured heat into the resulting useable heat or other forms of energy.

The heat recovering unit in a home or business is in the form of a heat generation unit, which houses a computing system. Once within said housing structure, heat can be captured and held within the unit. Thereafter, said heat can be transferred for other uses. This computing system could be cooled with a series of heat exchangers mounted in direct contact with heat generating components, e.g. computer processors and memory, or the system could be submerged in a dielectric liquid coolant/heat transfer fluid that is circulated through a heat exchanger. The heat recovering unit further comprises at least one control valve that controls the amount of exhaust heat fed to the heat exchanger. The control of exhaust hear recovery is based on the results of temperature sensor and other sensors and instruction of software. The detailed construction and operation of the heat exchanger is known in the art and is therefore not described herein. It is contemplated that any suitable commercially available heat exchanger could be employed in the system of this invention.

The reclaimed heat from computer processors and memory can be used to heat hot water, conditioned spaces and used as a heat source for absorption refrigeration systems used for air conditioning and food refrigeration. This heat exchanger could supply many different devices, such as:
Storage tank to heat domestic hot water;
Adsorptive refrigeration unit to convert the heat to refrigeration for the preservation of food;
Absorption refrigeration system to convert he heat to refrigeration to air-condition living space;
Hydronic conditioned space heating system;
Heat exchange coil to heat forced air for conditioned space;
Heat exchanger to dry clothing;
A large storage tank to thermally store heat energy created by renewable generation for use at a later time;
Recovered heat for low temperature cooking processes in restaurants;
Preheaters for commercial boiler systems; and
Creating heat for process loads.

This system requires software to control the timing and intensity of the computation used in the production of heat. The system will use predictive algorithms to learn and refine the patterns of heat requirement of the house or building to accurately predict when occupants will require heat energy to ensure that the byproduct of that energy is available for each respective load listed above and that minimal heat is wasted or produced when it is not needed. Such predicting patterns can be based off of a memory system that keeps track of manual input for a set period of time. After said period of time lapses a predicting system is able to replicate such requirements without the need for further manual input.

The system will also employ various control strategies to optimize the efficiency of heat production and computation.

The system of the present invention may further comprise an electric generator that is driven by the heat recovering unit such that the thermal energy can be converted to other form of energy.

The more important features of the invention have been outlined so that the more detailed description that follows may be better understood and that the present contribution to the art may better be appreciated. Additional features of the invention will be described hereinafter and will form the subject matter of the claims that follow.

Before explaining at least one embodiment of the invention in detail, it is to be understood that the invention is not limited in its application to the details of construction and the arrangements of the components set forth in the following description or illustrated in the drawings. The invention is capable of other embodiments and of being practiced and carried out in various ways. Also it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods and systems for carrying out the several purposes of the present invention. It is important, therefore, that the claims be regarded as including such equivalent constructions insofar as they do not depart from the spirit and scope of the present invention.

The foregoing has outlined, rather broadly, the preferred feature of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention and that such other structures do not depart from the spirit and scope of the invention in its broadest form.

### BRIEF DESCRIPTION OF THE DRAWINGS

Other aspects, features, and advantages of the present invention will become more fully apparent from the following detailed description, the appended claim, and the accompanying drawings in which similar elements are given similar reference numerals.

FIG. 1 is a perspective view of a distributed computing and combined computation exhaust heat recovery system according to one embodiment of the present invention.

FIG. 2 is a perspective view of a distributed computing and combined computation exhaust heat recovery system according to another embodiment of the present invention.

FIG. 3 is a perspective view of a distributed computing and combined computation exhaust heat recovery system according to another embodiment of the present invention.

### DESCRIPTION OF THE PREFERRED EMBODIMENT

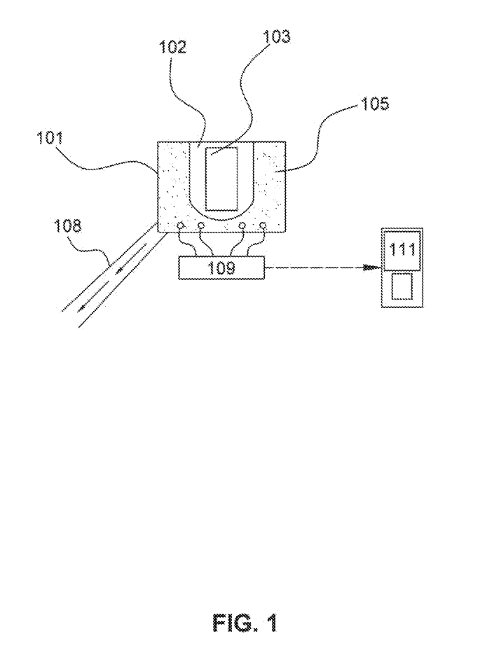

Referring to FIG. 1, there is disclosed a distributed computing and combined heat system according to one embodiment of the present invention.

The system comprises a container 101 with a recess 102 in the center for housing a computing unit 103. The container 101 is filled with heal absorbing, dielectric material such as mineral oil 105. When the computing unit is put in the central recess of the container, the computing unit is surrounded by dielectric fluid. Because the container is made of heat absorbing material, the heat from computing unit due to computation is efficiently transferred through the container's wall to dielectric fluid. The heat generated by the computing unit 103 is transferred into the dielectric fluid 105 at a rate much higher than air. Then, the dielectric fluid is pumped through a heat exchanger (radiator) to dissipate the heat into a heating medium 108 which includes but is not limited to air, water, etc. The heating medium can then be used for household/building heating and other purposes. The sensors 109 including but not limited to temperature detectors are attached to the heat recovering unit so as to transfer data to the computing unit and/or a central computer 111 which has software to control the timing and intensity of the computation used in the production of heat.

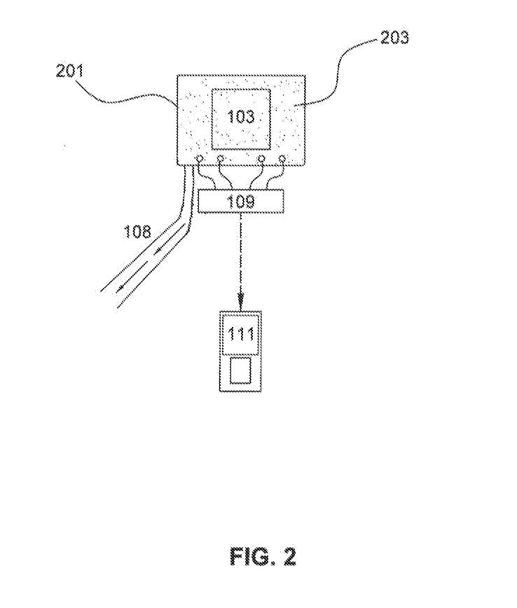

In another embodiment as illustrated in FIG. 2, the system 100 comprises a container 201 filled with a dielectric liquid coolant 203 that is circulated through a heat exchanger. A computing unit 103 is submerged in the dielectric liquid coolant 203 in the container 201. The dielectric liquid coolant carrying the heat generated from computation flows through heat exchanger such as radiator coils and heating medium (e.g. air or water) flows past the coils, which cools the coolant and heats the incoming heating medium which includes but is not limited to air or water, etc. The hot air/water may then be circulated by pumps through radiators within the building. The hot air/water can then be used to heat storage tank to heat domestic water, to dry clothing, heating space, radiates to condition space heating system, etc. The heat recovering unit may further comprise control valves, pumps, pipes, etc. The detailed construction and operation of the heat exchanger is known in the art and is therefore not described herein. It is contemplated that any suitable commercially available heat exchanger could be employed in the system of this invention.

This heat exchanger could supply many different devices:
Storage tank to heat domestic hot water;
Adsorptive refrigeration unit to convert the heat to refrigeration for the preservation of food;
Absorption refrigeration system to convert the heat to refrigeration to air-condition living space;
Radiant conditioned space heating system;
Heat exchange coil to heat forced air for conditioned space;
Heat exchanger to dry clothing;
A large storage tank to thermally store heat energy created by renewable generation for use at a later time;
Recovered heat for low temperature cooking processes in restaurants;
Preheaters for commercial boiler systems; and
Creating heat for process loads.

The distributed computing and combined heat system 100 further comprises software to control the timing and intensity of the computation used in the production of heat. The system will predict when occupants will require heat energy to ensure that the byproduct of that energy (or computation) is available for each respective load listed above and that minimal heat is wasted or produced when it is not needed. The system may further comprise an electric generator that is driven by the heat recovering unit to convert thermal energy to other forms of energy such as electric current.

The system further comprises sensors 109 attached to the container 201 and employ various strategies to optimize the efficiency of the heat production and computation.

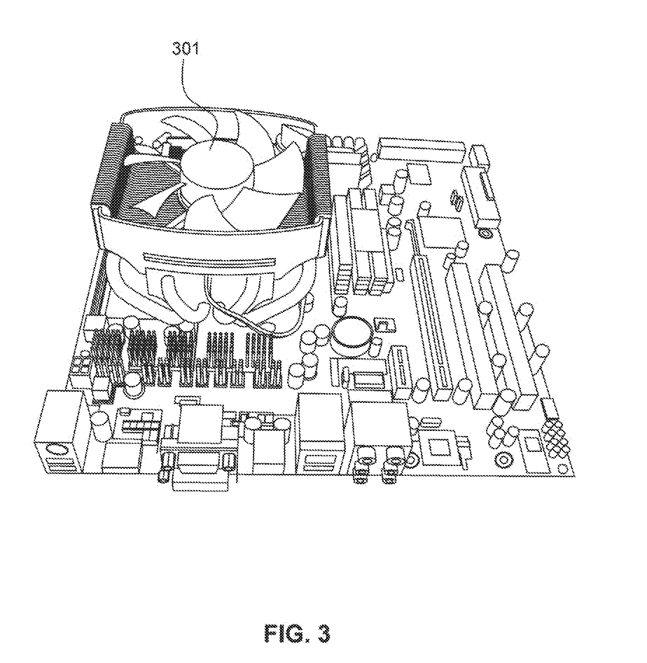

Referring to FIG. 3, another embodiment of the system 100, wherein the heat recovering unit 101 comprises a series of heat exchangers 301 mounted in direct contact with heat generating components of the computing unit such as processor and memory. The heat produced by computation can be transferred to incoming heating medium which includes but is not limited to air and water as described in the foregoing paragraphs.

A method of providing distributed computing and combined heat comprises: providing at least one heat generation unit such as a computing unit; providing at least one exhaust heat recovering unit such as the aforementioned example which houses the heat generation computing unit; providing software and providing at least one sensor, wherein the computing unit generates heat while performing computation, the heat is recovered by the heat recovering unit which converts the heat into usable heat, the software is used to control timing and intensity of the computation used in the production of heat, and the sensors are attached to the heat recovering unit to transfer data to the central computer.

The software used to support the distributed computation and combined computation exhaust heat recovery system comprises components to transform the computation into a variable load that can be scaled up and down depending on the system requirement for heat; components to receive input from computing unit and heat recovering unit and send output to computing unit and heat recovering unit; components to predict when occupants will require heat energy to ensure that the byproduct of that energy is available; and components to control the timing and intensity of the computation used in the production of heat.

While there have been shown and described and pointed out the fundamental novel features of the invention as applied to the preferred embodiments, it will be understood that the foregoing is considered as illustrative only of the principles of the invention and not intended to be exhaustive or to limit the invention to the precise forms disclosed. Obvious modifications or variations are possible in light of the above teachings. The embodiments discussed were chosen and described to provide the best illustration of the principles of the invention and its practical application to enable one of ordinary skill in the art to utilize the invention in various embodiments and with various modifications as are suited to the particular use contemplated All such modifications and variations are within the scope of the invention as determined by the appended claims when interpreted in accordance with the breadth to which they are entitled.

What is claimed is:

1. A system for recovering, transforming, and converting the heat generated from distributed computing unit to usable heat, the system comprising:
at least one computing unit;
at least one heat recovering unit;
software;
at least one sensor; and
a central computer;
wherein the computing unit generates heat while performing computation, the heat is recovered by the heat recovering unit which converts the heat into usable heat or other forms of energy, the software is used to control timing and intensity of the computation used in the production of heat, and the sensors are attached to the heat recovering unit to transfer data to the central computer.

2. The system of claim 1, wherein the heat recovering unit comprising a container filled with circulating dielectric liquid coolant and at least one heat exchanger, wherein the computing unit is submerged in the the dielectric liquid coolant which absorbing heat and carrying the heat generated from computation to the heat exchangers and transferring heat to an incoming medium which includes but is not limited to air or water.

3. The system of claim 1, wherein the heat recovering unit comprising a series of heat exchangers which are mounted in direct contact with heat generating components including but not limited to processor and memory of the computing unit.

4. The system of claim 1, wherein the heat exchanger could supply many different devices:
storage tank to heat domestic hot water;
absorptive refrigeration unit to convert the heat to refrigeration for the preservation of food;
absorptive or adsorptive refrigeration system to convert the heat to refrigeration to air-condition living space;
hydronic conditioned space heating system;
heat exchange coil to heat forced air for conditioned space;
heat exchanger to dry clothing;
a large storage tank to thermally store heat energy created by renewable generation for use at a later time;
recovered heat for low temperature cooking processes in restaurants;
preheaters for commercial boiler systems; and
creating heat for process loads.

5. The system of claim 1, further comprising various control means to optimize the efficiency of heat production and computation.

6. The system of claim 1, wherein the software comprising:
components to transform the computation into a variable load that can be scaled up and down depending on the system requirement for heat;
components to receive input from computing unit and heat recovering unit and send output to computing unit and hear recovering unit;
components to predict when occupants will require heat energy to ensure that the byproduct of that energy is available; and
components to control the timing and intensity of the computation used in the production of heat.

7. The system of claim 1, further comprising an electric generator that is driven by the hear recovering unit.

8. A method of for recovering, transforming, and converting the heat generated from distributed computing unit to usable heat, the method comprising:
providing at least one computing unit;
providing at least one heat recovering unit;
providing software;
providing at least one sensor; and
a central computer;
wherein the computing unit generates heat while performing computation, the heat is recovered by the heat recovering unit which converts the heat into usable heat, the software is used to control timing and intensity of the computation used in the production of heat, and the sensors are attached to the heat recovering unit to transfer data to the computing unit and/or central computer.

9. The method of claim 8, wherein the heat recovering unit comprising a container filled with circulating dielectric liquid coolant and at least one heat exchanger, wherein the computing unit is submerged in the the dielectric liquid coolant which absorbing heat and carrying the heat generated from computation by the computing unit to heat exchangers and transferring heat to an incoming airflow.

10. The method of claim 8, wherein the heat recovering unit comprising a series of heat exchangers which are mounted in direct contact with heat generating components of the computing unit.

11. The method of claim 8, wherein the heat exchanger could supply many different devices:
storage tank to heat domestic hot water;
absorptive refrigeration unit to convert the heat to refrigeration for the preservation of food;
absorptive refrigeration system to convert the heat to refrigeration to air-condition living space;
radiant conditioned space heating system;
heat exchange coil to heat forced air for conditioned space;
heat exchanger to dry clothing;
a large storage tank to thermally store heat energy created by renewable generation for use at a later time;
recovered heat for low temperature cooking processes in restaurants;
preheaters for commercial boiler systems; and
creating heat for process loads.

12. The method of claim 8, further comprising providing various control strategies/means to optimize the efficiency of heat production and computation.

13. The method of claim 8, wherein the software comprising:
components to transform the computation into a variable load that can be scaled up and down depending on the system requirement for heat;
components to receive input from computing unit and heat recovering unit and send output to computing unit and heat recovering unit;
components to predict when occupants will require heat energy to ensure that the byproduct of that energy is available; and
components to control the timing and intensity of the computation used in the production of heat.

14. The method of claim 8, further comprising providing an electric generator that is driven by the heat recovering unit.
